(19) United States
(12) Patent Application Publication
(10) Pub. No.: US 2022/0139705 A1
(43) Pub. Date: May 5, 2022

(54) METHOD OF FORMING OXIDE LAYER AND SEMICONDUCTOR STRUCTURE

(71) Applicant: CHANGXIN MEMORY TECHNOLOGIES, INC., Hefei (CN)

(72) Inventor: Yufeng GUO, Hefei (CN)

(73) Assignee: CHANGXIN MEMORY TECHNOLOGIES, INC., Hefei (CN)

(21) Appl. No.: 17/648,420

(22) Filed: Jan. 19, 2022

Related U.S. Application Data
(63) Continuation of application No. PCT/CN2021/106925, filed on Jul. 16, 2021.

(30) Foreign Application Priority Data
Sep. 29, 2020 (CN) 202011049227.7

(51) Int. Cl. H01L 21/02

(52) U.S. Cl. CPC H01L 21/02238; H01L 21/02164

(57) ABSTRACT

A method of forming an oxide layer includes: providing a substrate; forming an oxide film structure: introducing hydrogen into a reaction environment, introducing oxygen, and forming the oxide film structure on a surface of the substrate; performing annealing treatment: introducing compensation gas into the reaction environment, and performing pulse annealing treatment on the oxide film structure to form an oxide layer film; and repeating at least two cycles including the above steps to form at least two oxide layer films stacked on the surface of the substrate so as to form the oxide layer.

### CROSS-REFERENCE TO RELATED APPLICATIONS

This is a continuation of International Application No. PCT/CN2021/106925 filed on Jul. 16, 2021, which claims priority to Chinese Patent Application No. 202011049227.7 filed on Sep. 29, 2020. The disclosures of the above-referenced applications are hereby incorporated by reference in their entirety.

### BACKGROUND

In an In-Situ Steam Generation (ISSG) process, a large number of gas-phase activated radicals are generated in a low-pressure high-temperature treatment environment, wherein the gas-phase activated radicals mainly contain oxygen atoms, oxygen radicals, hydroxyl groups, water molecules and the like.

### SUMMARY

The present disclosure relates to the technical field of semiconductor preparation process, and in particular to a method of forming an oxide layer and a semiconductor structure.

An aspect of the present disclosure provides a method of forming an oxide layer, including:

providing a substrate;

forming an oxide film structure: introducing hydrogen into a reaction environment, introducing oxygen, and forming the oxide film structure on a surface of the substrate;

performing annealing treatment: introducing compensation gas into the reaction environment, and performing pulse annealing treatment on the oxide film structure to form an oxide layer film; and

repeating at least two cycles comprising the above steps to form at least two oxide layer films stacked on the surface of the substrate so as to form the oxide layer.

### BRIEF DESCRIPTION OF THE DRAWINGS

FIG. 1 is a schematic process diagram in a step of a method of forming an oxide layer shown according to an exemplary implementation.

FIG. 2 is a schematic structural diagram of a semiconductor structure treated through the process step shown in FIG. 1.

FIG. 3 is a schematic process diagram in another step of a method of forming an oxide layer shown according to an exemplary implementation.

FIG. 4 is a schematic structural diagram of a semiconductor structure treated through the process step shown in FIG. 3.

FIG. 5 is a process timing diagram of introducing states of various kinds of gases in a method of forming an oxide layer shown according to an exemplary implementation.

FIG. 6 is a process timing diagram of introducing states of various kinds of gases in a method of forming an oxide layer shown according to another exemplary implementation.

FIG. 7 is a process timing diagram of introducing states of various kinds of gases in a method of forming an oxide layer shown according to another exemplary implementation.

Reference numerals are as follows:
100, substrate;
200, oxide film structure;
201, oxide layer film;
210, void;
220, Si—H bonds and Si—OH bonds;
300, oxide layer.

### DETAILED DESCRIPTION

Exemplary implementations will now be described more fully with reference to the accompanying drawings. However, the exemplary implementations can be implemented in a variety of forms and should not be construed as limited to the implementations set forth herein; rather, these implementations are provided so that the present disclosure will be thorough and complete, and will fully convey the concept of exemplary implementations to those skilled in the art. The same reference numerals in the drawings denote the same or similar structures, and thus their detailed description will be omitted

When the activated radicals are subjected to oxidation reaction with silicon (Si) of a substrate of a semiconductor structure, a small amount of Si—H bonds and Si—OH bonds are generated. Due to the poor stability of the Si—H bonds and Si—OH bonds, impurity defects are generated in an oxide layer (such as a gate oxide film). Furthermore, since the oxygen atoms of the activated radicals react rapidly at the interface of silicon and silicon dioxide, so that a part of the generated silicon dioxide has reacted without being regularly arranged, voids are easily formed at the interface, and defects are also brought to the oxide layer.

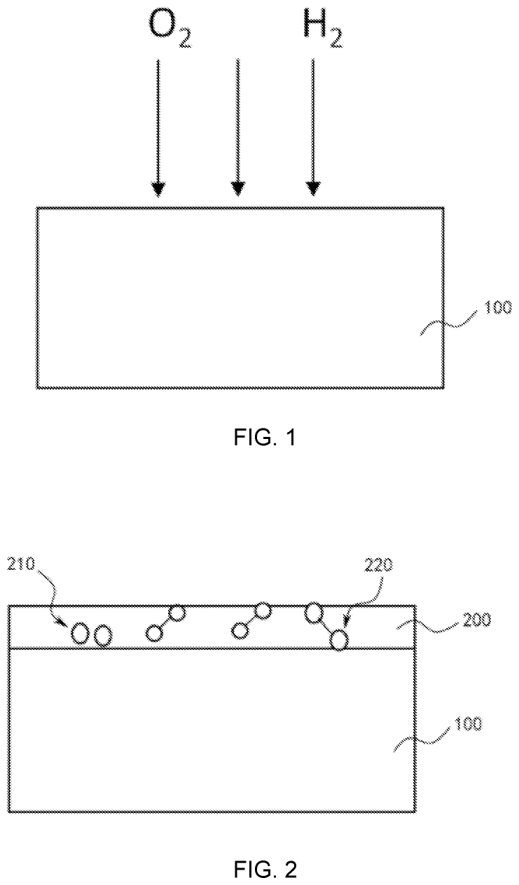

Referring to FIG. 1, a schematic process diagram in one step of a method of forming an oxide layer provided by the present disclosure is representatively shown. In this exemplary implementation, the method of forming the oxide layer provided by the present disclosure is illustrated by an example of a construction process applied to a semiconductor memory device, particularly to a memory component device. Those skilled in the art will readily appreciate that various modifications, additions, substitutions, deletions, or other changes are made to the specific implementations described below for applying the relevant designs of the present disclosure to other types of semiconductor structures, these changes are still within the scope of the principle of the method of forming the oxide layer provided in the present disclosure.

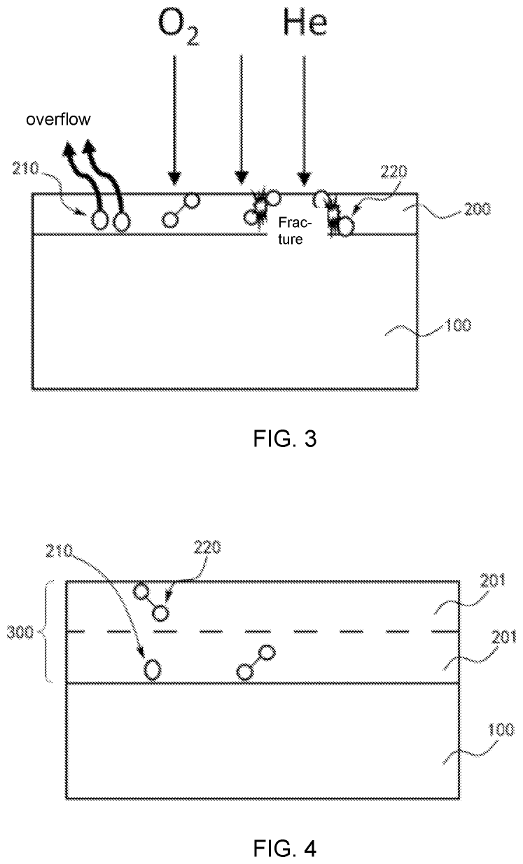

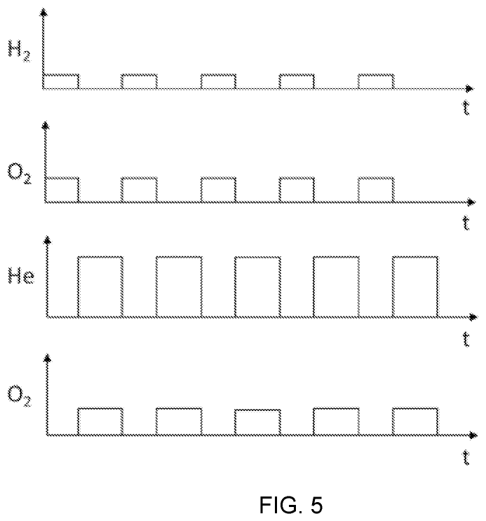

Referring to FIGS. 2 to 7, FIG. 2 representatively shows a schematic structural diagram of a semiconductor structure treated through the process step shown in FIG. 1. FIG. 3 representatively shows a schematic process diagram in another step. FIG. 4 representatively shows a schematic structural diagram of a semiconductor structure treated through the process step shown in FIG. 3. FIGS. 5 to 7 representatively show process timing diagrams of introducing states of various kinds of gases in various implementations, respectively. Hereinafter, the process method, parameters, and sequence of the main steps of the method of forming the oxide layer provided by the present disclosure will be described in detail with reference to the above accompanying drawings.

As shown in FIGS. 1 to 4, in this implementation, the method of forming the oxide layer provided by the present disclosure can be used to form an oxide layer 300 on a substrate 100 of a semiconductor structure. The substrate 100 of the semiconductor structure may be a silicon substrate 100, and the material of the oxide layer 300 may include silicon dioxide (SiO₂), such as a gate oxide film of a semiconductor memory device. Specifically, the method of forming the oxide layer provided by the present disclosure mainly comprises:

providing a substrate 100;

forming an oxide film structure 200: introducing hydrogen (H₂) into a reaction environment, introducing oxygen (O₂), and forming the oxide film structure 200 on a surface of the substrate 100;

performing annealing treatment: introducing compensation gas into the reaction environment, and performing pulse annealing treatment on the oxide film structure 200 to form an oxide layer film 201; and

repeating at least two cycles comprising the above steps to form at least two oxide layer films 201 stacked on the surface of the substrate 100 so as to form the oxide layer 300.

As described above, the method of forming the oxide layer provided by the present disclosure can reduce unstable Si—H bonds and Si—OH bonds 220 existing in silicon dioxide by adopting the compensation gas for performing the pulse annealing treatment. In addition, the present disclosure performs the formation of the oxide film structure 200 and the annealing treatment alternately by adopting a plurality of cycles, so that the annealing treatment stage by adopting the compensating gas is prolonged, more sufficient time and heat energy are provided for the self-healing of surface defects of the substrate 100 of the semiconductor structure, the defects of the surface and the interface of the substrate 100 are obviously reduced, and the product yield of the semiconductor structure is greatly improved.

It should be noted that in this implementation, the method of forming the oxide layer including two above process cycles is as an example. In other implementations, the method of forming the oxide layer may also include three or more of the above process cycles. Also, the reaction environment referred to in this specification may be understood as a process environment in which the semiconductor structure is placed and the oxide layer 300 is formed, for example, a reaction chamber such as a furnace tube. In this implementation, an environmental condition of the reaction environment may be, for example, a low-pressure high-temperature environment.

Referring to FIG. 1, in this implementation, in “forming the oxide film structure 200”, the oxygen and the hydrogen are introduced into the reaction environment, so that a small amount of oxide is formed on the surface of the substrate 100 of the semiconductor structure, and therefore the oxide film structure 200 is formed. Accordingly, the present disclosure can realize that a desired oxide film is formed by stacking through a plurality of process cycles by controlling the thickness of the oxide film structure 200 formed in each process cycle.

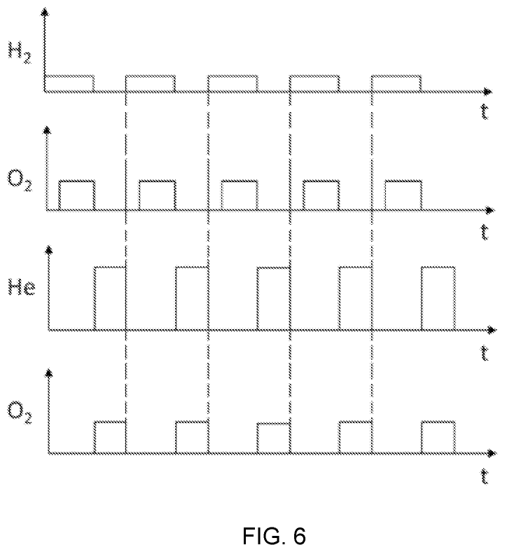

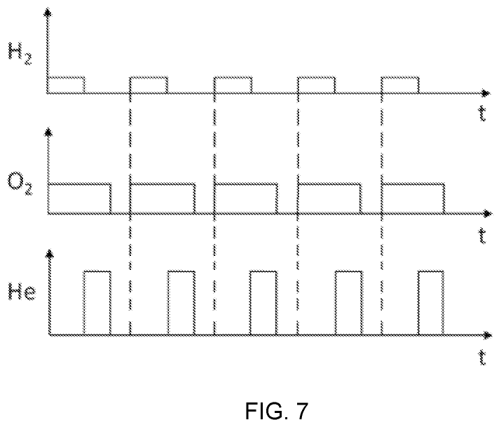

Optionally, in this implementation, in “forming the oxide film structure 200”, the oxygen and the hydrogen are introduced in a simultaneous opening manner (as shown in FIGS. 5 and 7). In other implementations, in “forming the oxide film structure 200”, introduction of the oxygen and the hydrogen may be opened at different times. For example, the oxygen is opened first, and the hydrogen is opened after a predetermined time interval; for another example, the hydrogen is opened first, and the oxygen is opened after a predetermined time interval (as shown in FIG. 6), which is not limited to this implementation.

Optionally, in this implementation, in “forming the oxide film structure 200”, the oxygen and the hydrogen are introduced in a simultaneous closing manner (as shown in FIGS. 5 and 7). In other implementations, in “forming the oxide film structure 200”, introduction of the oxygen and the hydrogen may be closed at different times. For example, the oxygen is closed first, and the hydrogen is closed after a predetermined time interval; for another example, the hydrogen is closed first, and the oxygen is closed after a predetermined time interval (as shown in FIG. 7), which is not limited to this implementation.

It should be noted that in “forming the oxide film structure 200”, introduction of the oxygen and the hydrogen is required to have a coincident stage, i.e., a stage in which the oxygen and the hydrogen are simultaneously introduced, for the formation of the oxide film structure 200. In addition, the timing state of each step in each process cycle in this implementation can refer to the timing state of each step in a single process cycle shown in FIG. 5.

Optionally, in this implementation, in “forming the oxide film structure 200”, a flow at which the oxygen is introduced may be greater than a flow at which the hydrogen is introduced.

Referring to FIG. 2, an exemplary structure of the substrate 100 of the semiconductor structure is representatively shown after “forming the oxide film structure 200” described above. Specifically, a layer of oxide film structure 200 having voids 210 and Si—H bonds and Si—OH bonds 220 is formed on the substrate 100 in this step.

In this implementation, in “performing the annealing treatment”, on the basis of introducing the compensating gas into the reaction environment, the oxygen can be further introduced, so that the annealing effect on the oxide film structure 200 can be optimized, an overflow amount of the voids 210 and a fracture probability of the Si—H bonds and the Si—OH bonds 220 are increased, defects of the oxide layer film 201 formed by annealing are further reduced, and on this basis, annealing treatment time can be reduced

Referring to FIG. 3, in this implementation, in “performing the annealing treatment”, the compensation gas is introduced into the reaction environment, and the oxygen is introduced again whereby the formed oxide film structure 200 is subjected to pulse annealing, so that at least a part of voids 210 in the oxide film structure 200 overflow and at least a part of the Si—H bonds and Si—OH bonds 220 are fractured. Thus, the oxide layer film 201 is formed.

Optionally, in this implementation, in “performing the annealing treatment”, the oxygen and the compensation gas are introduced in a simultaneous opening manner (as shown in FIGS. 5 and 6). In other implementations, in “performing the annealing treatment”, introduction of the oxygen and the hydrogen may be opened at different times. For example, the oxygen is opened first, and the compensation gas is opened after a predetermined time interval; for another example, the compensation gas is opened first, and the oxygen is opened after a predetermined time interval, which is not limited to this implementation.

Optionally, in this implementation, in “performing the annealing treatment”, the oxygen and the compensation gas are introduced in a simultaneous closing manner (as shown in FIGS. 5 and 6). In other implementations, in “performing the annealing treatment”, introduction of the oxygen and the hydrogen may be closed at different times. For example, the oxygen is closed first, and the compensation gas is closed after a predetermined time interval; for another example, the compensation gas is closed first, and the oxygen is closed after a predetermined time interval, which is not limited to this implementation.

It should be noted that in “performing the annealing treatment”, the introduction of the oxygen and the introduction of the compensation gas need to have a coincident stage, i.e. a stage at which the oxygen and the compensation gas are introduced simultaneously, for realizing pulse annealing. In addition, the timing state of each step in each process cycle in this implementation can refer to the timing state of each step in a single process cycle shown in FIG. 5.

Optionally, in this implementation, in “performing the annealing treatment”, the content ratio of the oxygen introduced in this step to the compensation gas introduced in this step may be 2:100˜15:100, such as 2:100, 5:100, 10:100, 15:100, etc. In other implementations, the content ratio of the oxygen introduced in annealing treatment to the compensation gas introduced in annealing treatment may also be less than 2:100, or may be greater than 15:100, such as 1.5:100, 16:100, etc., which is not limited to this implementation.

Optionally, in this implementation, in “performing the annealing treatment”, the treatment time of this step may be 2 s-60 s, such as 2 s, 10 s, 25 s, 60 s, etc. Herein, the so-called “treatment time” can be understood as a stage in which the oxygen and the compensation gas are simultaneously introduced in this step. In other implementations, the treatment time of the annealing treatment may also be less than 2 s, or may be greater than 60 s, such as 1.9 s, 65 s, etc., may be flexibly adjusted according to the thickness of the oxide layer film 201 to be formed in a single process cycle, which is not limited in this implementation.

Optionally, in this implementation, in “performing the annealing treatment”, the treatment temperature of this step may be 600° C.˜1200° C., such as 600° C., 800° C., 950° C., 1200° C., etc. In other implementations, the treatment temperature of the annealing treatment may also be below 600° C., or may be above 1200° C., such as 595° C., 1210° C., etc., which is not limited to this implementation.

Optionally, in this implementation, in “performing the annealing treatment”, the compensation gas may include helium (He), wherein the helium is more inert than the oxygen. In other implementations, other gas which is more inert than oxygen may be used as the compensation gas, such as nitrogen (N₂), as well as other inert gas, which is not limited to this implementation.

Optionally, in this implementation, in a process cycle including the above “forming the oxide film structure 200” and “performing the annealing treatment”, the treatment temperature at which the oxide film structure 200 is formed may be the same as the treatment temperature at which the annealing treatment is performed, so that a better thermal budget and a better temperature uniformity are further ensured. In other implementations, the treatment temperature at which the oxide film structure 200 is formed and the treatment temperature at which the annealing treatment is performed may also be different, which is not limited in this implementation.

Optionally, in this implementation, in a process cycle including the above “forming the oxide film structure 200” and “performing the annealing treatment”, the reaction environment may be vacuumized after the formation of the oxide film structure 200. Accordingly, when the reaction environment returns to a vacuum state or approaches to the vacuum state, the compensation gas and the oxygen are introduced into the reaction environment for the annealing treatment. Based on the fact that the reaction environment in this implementation is a low-pressure high-temperature environment, the low-pressure environment can enable residual gas (oxygen and hydrogen) in the previous step to be discharged in a gas switching process between the two steps. In other implementations, a separate vacuumizing apparatus and process may be used to vacuumize the reaction environment, which is not limited to this implementation.

Optionally, in this implementation, in two process cycles including the above “forming the oxide film structure 200” and “performing the annealing treatment”, the reaction environment may be vacuumized after completion of the first process cycle. Accordingly, when the reaction environment returns to a vacuum state or approaches the vacuum state, the hydrogen and the oxygen are introduced into the reaction environment for the next process cycle (forming the oxide film structure 200). Based on the fact that the reaction environment in this implementation is a low-pressure high-temperature environment, the low-pressure environment can enable residual gas (oxygen and compensation gas) in the previous step to be discharged in a gas switching process between the two steps. In other implementations, a separate vacuumizing apparatus and process may be used to vacuumize the reaction environment, which is not limited to this implementation.

Based on the above detailed description of one exemplary implementation of the method of forming the oxide layer provided by the present disclosure, several other exemplary implementations of the method of forming the oxide layer will be described below in conjunction with FIGS. 5 to 7 from a process timing perspective. Herein, each of the following implementations has substantially the same process design as this implementation, and the following is a detailed description of main differences among the implementations.

As shown in FIG. 5, in this implementation, the method of forming the oxide layer provided by the present disclosure includes five process cycles, i.e., the above forming the oxide film structure and performing the annealing treatment are alternately cycled five times. On this basis, according to the thickness of the oxide layer to be finally formed, the thickness of the oxide film structure to be formed in each process cycle can be obtained, for example, one fifth of the thickness of the oxide layer (for example, the thicknesses of the oxide film structures which are formed in all the cycles are equal).

Optionally, as shown in FIG. 5, in this implementation, for one process cycle, in forming the oxide film structure, the oxygen and the hydrogen are simultaneously opened and simultaneously closed. Then, in performing the annealing treatment, the oxygen and the compensation gas are simultaneously opened and simultaneously closed.

Optionally, as shown in FIG. 5, in this implementation, the introduction time and the introduction amount of the fixed same gas in the same step of each process cycle are the same, that is, the thickness of each oxide film structure is approximately the same. In other implementations, the same gas in the same step, in different process cycles, may also be introduced at different times and amounts to obtain oxide film structures with different thicknesses.

As shown in FIG. 6, in this implementation, in forming the oxide film structure, the hydrogen is introduced into the reaction environment first, and the oxygen is introduced into the reaction environment during the introduction of the hydrogen. In other implementations, the oxygen may be introduced first, and the hydrogen is introduced during the introduction of the oxygen, which is not limited to this.

Optionally, as shown in FIG. 6, in this implementation, in forming the oxide film structure, the hydrogen and the oxygen are simultaneously closed. In other implementations, the hydrogen may be closed first, or the oxygen may be closed first, which is not limited to this.

As shown in FIG. 7, in this implementation, the oxygen participating in the formation of the oxide film structure and the oxygen participating in the annealing treatment may be continuously introduced in one process cycle. On this basis, the timing state of one process cycle roughly includes: opening hydrogen and oxygen→closing hydrogen→opening compensation gas→closing oxygen and compensation gas.

Optionally, as shown in FIG. 7, in this implementation, in forming the oxide film structure, the hydrogen and the oxygen are simultaneously opened. In other implementations, the hydrogen may be opened prior to the oxygen, or the oxygen may be opened prior to the hydrogen, which is not limited to this.

Optionally, as shown in FIG. 7, in this implementation, the oxygen may be closed simultaneously with the compensation gas in performing the annealing treatment. In other implementations, the compensation gas may be closed prior to the oxygen, which is not limited to this.

It should be noted that, in the above detailed description with respect to FIGS. 5 to 7, the horizontal axes “t” of each of the accompanying drawings indicate the time in the timing state, the vertical axes “O₂”, “H₂”, “He” respectively indicate the amount of oxygen introduced, the amount of hydrogen introduced, the amount of helium introduced (the compensation gas is exemplified by helium), and that the vertical axis is zero indicates that the gas is closed. Herein, the timing state of each gas is exemplary only, and a length of a timing pattern thereof on the horizontal axis and height on the vertical axis are exemplary only to express the opening or closing, the relative introduction flow and relative introduction time of the gas in a certain step in this implementation. FIGS. 5 to 7 are intended to illustrate various process sequences in several implementations and are not intended to show or limit the specific steps and the introduction times and flows of gases, as described herein.

It should be noted herein that the method of forming the oxide layer illustrated in the accompanying drawings and described in this specification is only a few examples of the many processes which can employ the principles of the present disclosure. It should be clearly understood that the principles of the present disclosure are in no way limited to any details or any steps of the method of forming the oxide layer shown in the accompanying drawings or described in this specification.

Based on the above detailed description of several exemplary implementations of the method of forming the oxide layer provided by the present disclosure, an exemplary implementation of the semiconductor structure provided by the present disclosure will be described below.

In this implementation, the semiconductor structure provided by the present disclosure includes a substrate, an oxide layer is formed on a surface of the substrate. Wherein the oxide layer is formed by the method of forming the oxide layer provided by the present disclosure and described in detail in the above implementations.

It should be noted herein that the semiconductor structures shown in the accompanying drawings and described in this specification are merely a few examples of the many types of semiconductor structures which can employ the principles of the present disclosure. It is to be clearly understood that the principles of the present disclosure are in no way limited to any details or any structures of the semiconductor structures shown in the accompanying drawings or described in this specification.

In summary, the method of forming the oxide layer provided by the present disclosure can reduce unstable Si—H bonds and Si—OH bonds existing in silicon dioxide by adopting the compensation gas for the pulse annealing treatment. In addition, the present disclosure performs the formation of the oxide film structure and the annealing treatment alternately by adopting a plurality of cycles, so that the annealing treatment stage by adopting the compensating gas is prolonged, more sufficient time and heat energy are provided for the self-healing of surface defects of the substrate of the semiconductor structure, the defects of the surface and the interface of the substrate are obviously reduced, and the product yield of the semiconductor structure is greatly improved.

Although the present disclosure has been described with reference to several exemplary embodiments, it should be understood that the terms used are illustrative and exemplary rather than restrictive. As the present disclosure may be embodied in several forms without departing from the spirit or essential attributes thereof, it should be understood that the above embodiments are not limited by any of the details of the foregoing description, but rather should be construed broadly within the spirit and scope as defined in the appended claims, and therefore all changes and modifications which fall within the scope of the claims or the equivalent range thereof shall be covered by the accompanying claims.

What is claimed is:

1. A method of forming an oxide layer, comprising:
providing a substrate;
forming an oxide film structure: introducing hydrogen into a reaction environment, introducing oxygen, and forming the oxide film structure on a surface of the substrate;
performing annealing treatment: introducing compensation gas into the reaction environment, and performing pulse annealing treatment on the oxide film structure to form an oxide layer film; and
repeating at least two cycles comprising the above steps to form at least two oxide layer films stacked on the surface of the substrate so as to form the oxide layer.

2. The method of forming an oxide layer according to claim 1, wherein in the annealing treatment stage, oxygen is introduced into the reaction environment, and the compensation gas is more inert than the oxygen.

3. The method of forming an oxide layer according to claim 2, wherein the oxygen introduction during the formation of the oxide film structure and the oxygen introduction during the annealing treatment are continuous oxygen introduction processes.

4. The method of forming an oxide layer according to claim 1, in at least one cycle, the method further comprising:
vacuumizing the reaction environment after forming the oxide film structure.

5. The method of forming an oxide layer according to claim 1, wherein in forming an oxide film structure, the introducing the hydrogen and the oxygen into the reaction environment comprises:
introducing the hydrogen into the reaction environment; and
introducing the oxygen into the reaction environment in introducing process of the introducing the hydrogen.

6. The method of forming an oxide layer according to claim 1, wherein in performing the annealing treatment, a content ratio of introduced oxygen to introduced compensation gas is 2:100-15:100.

7. The method of forming an oxide layer according to claim 1, wherein treatment time of the annealing treatment is 2 s-60 s.

8. The method of forming an oxide layer according to claim 1, wherein treatment temperature of the annealing treatment is 600° C.-1200° C.

9. The method of forming an oxide layer according to claim 1, wherein in a same cycle, treatment temperature of forming the oxide film structure is the same as treatment temperature of performing the annealing treatment.

10. The method of forming an oxide layer according to claim 1, wherein the compensation gas comprises helium.

11. The method of forming an oxide layer according to claim 1, wherein the compensation gas comprises nitrogen.

12. A semiconductor structure, wherein an oxide layer is formed on a surface of a substrate of the semiconductor structure through the method of forming an oxide layer according to claim 1.
